(19) United States
(12) Patent Application Publication
(10) Pub. No.: US 2026/0282440 A1
(43) Pub. Date: Sep. 17, 2026

(54) POWER SEMICONDUCTOR DEVICE AND METHOD OF PRODUCING A POWER SEMICONDUCTOR DEVICE

(71) Applicant: Infineon Technologies Dresden AG & Co. KG, Dresden (DE)

(72) Inventors: Thomas Hunger, Dresden (DE); Matteo Dainese, München (DE)

(21) Appl. No.: 19/566,231

(22) Filed: Mar. 13, 2026

(30) Foreign Application Priority Data
Mar. 17, 2025 (DE) 102025110078.0

(51) Int. Cl. H10D 30/66; H10D 12/00; H10D 12/01; H10D 30/01; H10D 62/10

(52) U.S. Cl. CPC H10D 30/668; H10D 12/038; H10D 12/481; H10D 30/0297; H10D 62/126

(57) ABSTRACT

A power semiconductor device includes a semiconductor substrate with a drift region of a first conductivity type and trenches, two of which laterally confine a mesa. Each trench extends into the substrate along a vertical direction and includes an electrode. The device further includes a semiconductor body region of a second conductivity type in the mesa, a semiconductor source region of the first conductivity type, an insulation layer above and/or on the source region, and a recess in the mesa. The source region has a length extension along a first lateral direction parallel to a length extension of the trenches and a width extension along a second lateral direction perpendicular to the length extension. The source region covers only part of the semiconductor body region in the mesa along the first lateral direction, and at least part of the semiconductor body region in the mesa along the second lateral direction.

### TECHNICAL FIELD

The present disclosure relates to embodiments of a power semiconductor device and to embodiments of a method of producing a power semiconductor device.

### BACKGROUND

Power semiconductor devices are critical components in modern electronics, designed specifically to meet the demand of high-power applications. As such they are deployed in many industries, such as automotives and renewable energies, where they are used for switching, amplifying and regulating electrical power, handling large currents and voltages with minimal energy loss. Common types of power semiconductor devices comprise power MOSFETs (metal oxide semiconductor field effect transistors), IGBTs (insulated gate bipolar transistors), power diodes and thyristors.

A power semiconductor device usually comprises a semiconductor substrate configured to conduct a forward load current along a load current path between two load terminals of a device. Three-terminal devices additionally comprise a driving or control terminal, which is used to control the device state. For voltage-driven devices as the power MOSFET and IGBTs, the driving terminal is referred to as gate or gate electrode. Through application of a voltage to the gate electrode, conductivity of the semiconductor channel (MOSFET) or carrier injection (IGBT) are modulated. That means, an electric field modulates the current flow through the device.

Voltage-driven power semiconductor devices can have a vertical design, i.e. the forward load current flows along a load current path vertically through the device between two load terminals of the device, e.g. from a source terminal to a drain terminal (power MOSFET) or from an emitter terminal to a collector terminal (IGBT) through the semiconductor substrate. In a power MOSFET and in an IGBT, the forward load current path comprises a channel and a drift region.

In trench devices, the gate electrode is included in a trench of the power semiconductor device. Multiple trenches may be arranged in parallel in a stripe-like configuration. Correspondingly, between adjacent trenches elevated regions are formed which are called mesas. Mesas are for example used to define specific device regions, improve current spreading and improve breakdown-voltage performance. Such mesa is e.g. configured for providing a path for the forward load current, e.g. by including a source region and a body region. The gate is for example insulated from the load terminals, and from the load current path, by a thin insulating layer, often made of silicon dioxide. This insulating layer may also be referred to as trench insulator.

In order to provide for a path of the forward load current, a mesa must be electrically contacted with one of the load terminals of the power semiconductor device. To this end, a contact groove, i.e. a groove-like recess, may be provided in the mesa. Through a contact-plug structure in the contact groove, both the source region and the body region can be contacted. The overlap between the source region and the contact groove, i.e. the area where the contact groove physically intersects or overlaps with the source region, is referred to as source-contact overlap or contact overlap.

In a trench device, the center-to-center distance between neighboring trenches, i.e. the distance measured from the center of one trench to the center of its adjacent trench, is referred to as pitch or trench pitch. The width of the trench as measured at the surface layer is referred to as trench width. The width of the mesa, i.e. the distance measured at the surface layer from one sidewall of a trench to the next sidewall of the adjacent trench, is referred to as mesa width (also: active-area width or trench-to-trench spacing). Hence, the trench pitch is the sum of the mesa width and the trench width.

The mesa width plays a critical role in determining the electrical, thermal and physical characteristics of a power semiconductor device. E.g. in order to reduce the chip area, it is desirable to keep the mesa width small. A small mesa width allows for an increased accumulation of free carriers in the drift zone, thus reducing the ON-state voltage and increasing ON-state efficiency. Additionally, a reduced mesa width, and thus a reduced pitch of the cell, allows for a higher channel-width density, which also results in a reduced ON-state voltage.

To reduce the contact resistance and improve the electrical performance of power semiconductor devices, an implant, for example a doped implant is often deposited in the contact groove. This implant may ensure efficient device operation, especially in high-performance power applications. For example, the implant ions need to be activated, e.g. by thermal annealing. During the annealing, implanted ions can diffuse away from the implantation region, e.g. spreading into the channel region.

However, as the mesa width becomes smaller, diffusion of the implant material into the channel region becomes more important, affecting the threshold voltage and the electrical properties of the channel. This may lead to a shift in the threshold voltage, an increase in the off-state current and/or a reduced on/off ratio. For example, Boron as used in p-type implants shows a higher diffusion as compared to phosphorus or arsenic used in n-type implants. Therefore, in Boron-doped devices, and especially those with very short channels, it is crucial to control dopant diffusion when reducing the mesa width.

In view of this, the present disclosure enables the provision of a power semiconductor device with a reduced mesa width and a method for producing the same, wherein the negative effects resulting from implant diffusion are mitigated such that a threshold voltage shift is reduced by allowing a better control over the spatial separation of doped regions, for example in case of a Boron implant. In this way, a power semiconductor device, e.g. an IGBT, with enhanced bipolar conduction is provided.

### SUMMARY

According to one embodiment, a power semiconductor device comprises a semiconductor substrate with a drift region of a first conductivity type; a plurality of trenches, wherein two adjacent trenches laterally confine a mesa of the semiconductor substrate. Each trench extends from a semiconductor substrate surface into the semiconductor substrate along a vertical direction and comprises a trench electrode isolated from the semiconductor substrate by a trench insulator. The device further comprises a body region of a second conductivity type in the mesa; a source region of the first conductivity type. The body region may also be referred to as “semiconductor body region” and the source region may also be referred to as “semiconductor source region”. The source region has a length extension along a first lateral direction parallel to a length extension of the plurality of trenches and a width extension along a second lateral direction perpendicular to the length extension of the plurality of trenches. The source region covers only part of the body region in the mesa along the first lateral direction and covers at least part of the body region in the mesa along the second lateral direction. The device further comprises an insulation layer above and/or on the source region; and a recess in the mesa extending from an upper surface of the insulation layer along the vertical direction through the source region into the body region. The recess extends along the first lateral direction and comprises an interruption across at least part of the source region.

According to another embodiment, a method of producing a power semiconductor device is presented. The device includes, in a semiconductor substrate, a drift region of a first conductivity type; and a plurality of trenches, wherein two adjacent trenches laterally confine a mesa of the semiconductor substrate. Each trench extends from a semiconductor substrate surface into the semiconductor substrate along a vertical direction and comprises a trench electrode isolated from the semiconductor substrate by a trench insulator. The device further includes a body region of a second conductivity type in the mesa. The method comprises: forming a source region of the first conductivity type, wherein the source region has a length extension along a first lateral direction parallel to a length extension of the plurality of trenches and a width extension along a second lateral direction perpendicular to the length extension of the plurality of trenches. The source region covers only part of the body region in the mesa along the first lateral direction and covers at least part of the body region in the mesa along the second lateral direction. The method further comprises: forming an insulation layer above and/or on the source region; forming a recess in the mesa extending from an upper surface of the insulation layer along the vertical direction through the source region into the body region, wherein the recess extends along the first lateral direction and comprises an interruption across at least part of the source region.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically and exemplarily illustrates a power semiconductor device in accordance with one or more embodiments;

FIG. 2 schematically and exemplarily illustrates a section of a horizontal projection of a power semiconductor device according to one or more embodiments;

FIG. 3 schematically and exemplarily illustrates a section of a horizontal projection of a power semiconductor device in accordance with one or more embodiments;

FIG. 3A schematically and exemplarily illustrates a vertical cross-section along line A-A′ as indicated in FIG. 3 in accordance with one embodiment of a power semiconductor device;

FIG. 3B schematically and exemplarily illustrates a vertical cross-section along line A-A′ as indicated in FIG. 3 in accordance with one embodiment of a power semiconductor device;

FIG. 3C schematically and exemplarily illustrates a vertical cross-section along line B-B′ as indicated in FIG. 3 in accordance with one or more embodiments;

FIG. 4 schematically and exemplarily illustrates a section of a horizontal projection of a power semiconductor device in accordance with one or more embodiments;

FIG. 4A schematically and exemplarily illustrates a vertical cross-section along line A-A′ as indicated in FIG. 4 in accordance with one embodiment of a power semiconductor device;

FIG. 4B schematically and exemplarily illustrates a vertical cross-section along line A-A′ as indicated in FIG. 4 in accordance with one embodiment of a power semiconductor device;

FIG. 4C schematically and exemplarily illustrates a vertical cross-section along line B-B′ as indicated in FIG. 4 in accordance with one or more embodiments;

FIG. 5 schematically and exemplarily illustrates a section of a horizontal projection of a power semiconductor device in accordance with one or more embodiments;

FIG. 6A schematically and exemplarily illustrates a section of a horizontal projection of a power semiconductor device in accordance with one or more embodiments;

FIG. 6B schematically and exemplarily illustrates a section of a horizontal projection of a power semiconductor device in accordance with one or more embodiments; and

FIG. 7 schematically and exemplarily illustrates a method of producing a power semiconductor device in accordance with one or more embodiments.

### DETAILED DESCRIPTION

In the following detailed description, reference is made to the accompanying drawings which form a part hereof and in which are shown by way of illustration specific embodiment in which the solution may be practiced.

In this regard, directional terminology, such as “top”, “bottom”, “above”, “below”, “front”, “behind”, “back”, “leading”, “trailing”, “upper”, “lower” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction x and the second lateral direction y mentioned below can be horizontal directions, wherein the first lateral direction x and the second lateral direction y are perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction z mentioned below is an extension direction that is perpendicular to both the first lateral direction x and the second lateral direction y. The extension direction z is also referred to as “vertical direction z” herein.

In this specification, an “insulation layer above a source region” refers to an arrangement of an insulation layer above a source region, wherein at least one further layer may be arranged between the insulation layer and the source region. An “insulation layer on a source region” refers to an arrangement of an insulation layer directly on a source region, wherein no further layer is provided between the insulation layer and the source region.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

The term “semiconductor substrate refers to the entire bulk of semiconductor material that forms the foundation of the semiconductor device. The semiconductor substrate may also be referred to as “core” of the power semiconductor device.

The term “body region” or “semiconductor body region” as used in this specification refers to a specific part or section of the semiconductor substrate which has been engineered or doped to exhibit a particular characteristic or structure in the power semiconductor device. In one example, the semiconductor substrate comprises a drift region, e.g. below the body region.

In addition, in the context of the present specification, the term “insulation” or “insulating” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled. To give an example, two electrodes of a capacitor may be electrically insulated from each other and, at the same time, mechanically and capacitively coupled to each other, e.g., by means of an insulation, e.g., a dielectric.

The term “power semiconductor device” as used in this specification intends to describe a semiconductor device on a single chip with high voltage blocking and/or high current-carrying capabilities. In other words, such power semiconductor device is intended for high current, for example in the Ampere range, e.g., up to several ten or hundred Ampere, and/or high voltages, e.g. above 15 V, for example 100 V and above, e.g., up to at least 400 V or even more, e.g., up to at least 3 kV, or even up to 10 kV or more.

For example, the power semiconductor device described below may be a single semiconductor chip exhibiting a stripe-cell configuration (instead of a cellular configuration or a needle-cell configuration) and can be configured to be employed as a power component in a low-, medium- and/or high voltage application.

For example, the term “power semiconductor device” as used in this specification is not directed to logic semiconductor devices that are used for, e.g., storing data, computing data and/or other types of semiconductor-based data processing.

The present specification in one example relates to power semiconductor devices embodied as respective IGBTs, i.e., bipolar power semiconductor transistors that are controlled by insulated electrodes (gates), and power-MOSFETs, i.e., metal-oxide semiconductor field-effect transistors with a vertical structure which are controlled by insulated electrodes (gates).

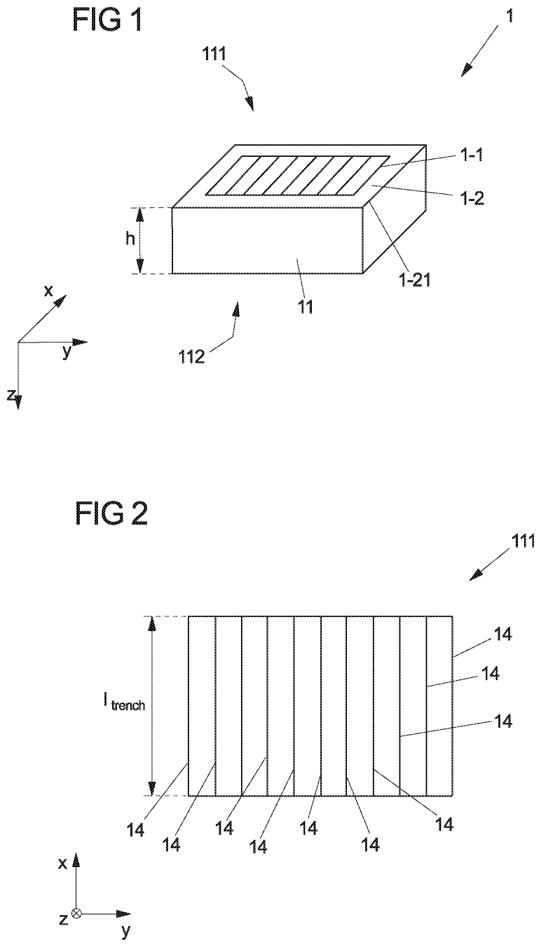

FIG. 1 schematically and exemplarily illustrates a power semiconductor device 1. The power semiconductor device 1 can be implemented within a single chip. The power semiconductor device 1 has an active region 1-1 with a plurality of transistor cells. The active region 1-1 is configured for load-current conduction and, if applicable, for switching. The active region 1-1 is surrounded by an edge-termination region 1-2. I.e., the edge-termination region 1-2 is external to and non-overlapping with the active region 1-1. The edge-termination region 1-2 is configured to provide blocking capabilities, guidance of the electrical field, potentially charge-carrier drainage and/or further functions associated with the protection and proper termination of the active region 1-1. The edge-termination region 1-2 is laterally terminated by an edge 1-21. For example, the edge 1-21 forms the chip edge of the power semiconductor device 1. The power semiconductor device 1 has a semiconductor substrate 11 having a frontside 111 and a backside 112. The frontside 111 is herein also referred to as semiconductor substrate surface 111. The frontside 111 and backside 112 vertically terminate the semiconductor substrate 11. The frontside 111 and the backside 112 extend laterally along the first lateral direction x and along the second lateral direction y. The semiconductor substrate 11 extends between the frontside 111 and the backside 112 along a vertical direction z. The distance between the frontside 111 and the backside 112 along the vertical direction z may be referred to as the thickness h of the semiconductor substrate 11.

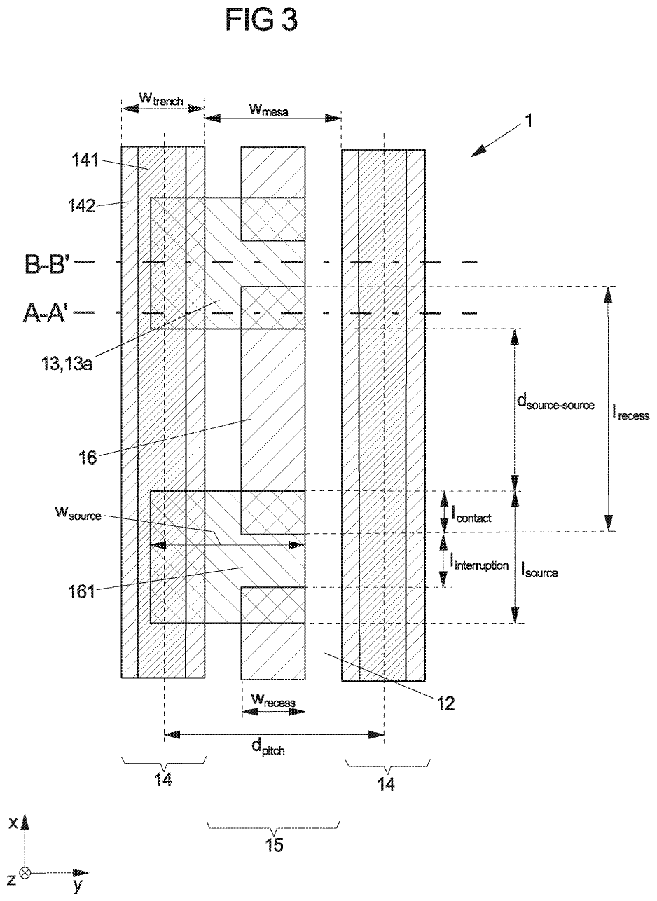

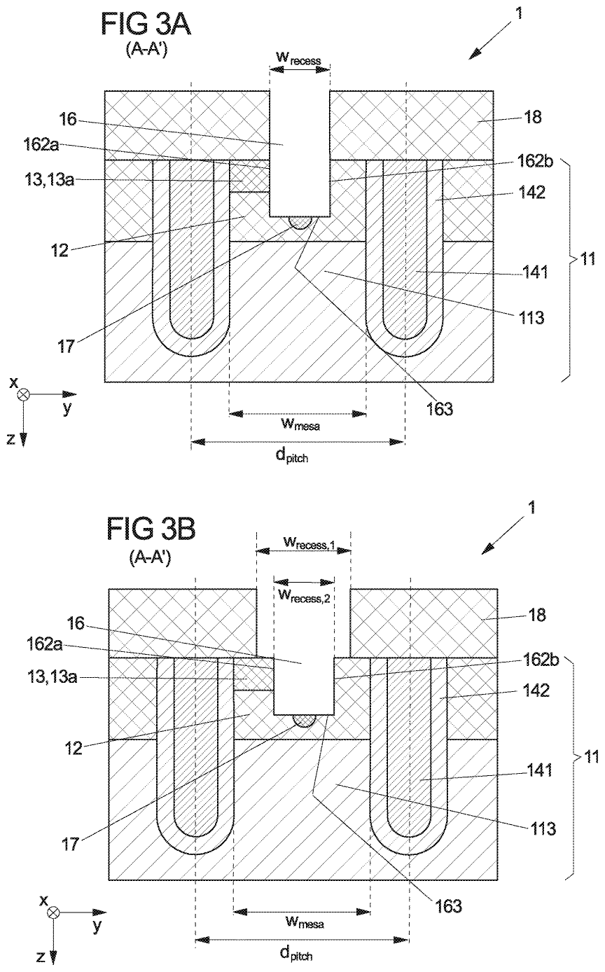

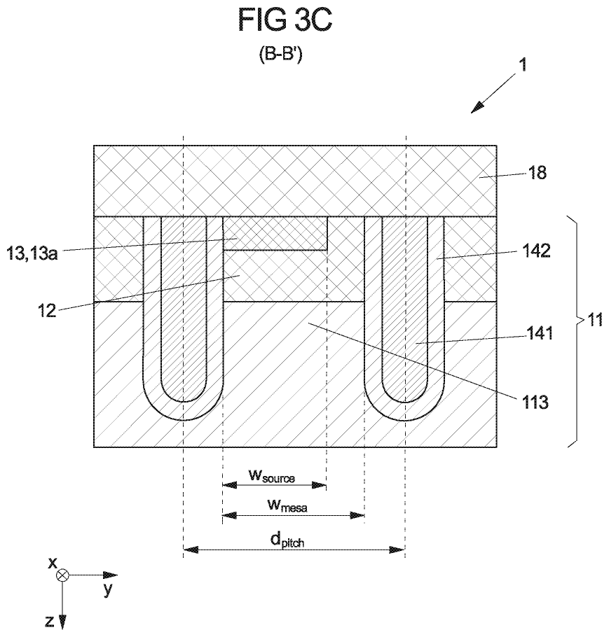

FIG. 2 schematically and exemplarily illustrates a section of a horizontal projection of a power semiconductor device 1, for example its active region 1-1 as described with regard to FIG. 1. FIG. 2 shows the part of a frontside 111 of a semiconductor device 1 in which the active region 1-1 is located. In the depicted embodiment, transistor cells are arranged in the active region 1-1 in a stripe-cell configuration. As will be described with regard to the following FIG. 3, the transistor cells are separated by trenches 14, whereas each trench 14 may be shared between two adjacent transistor cells. In the example depicted in FIG. 2, the stripes, i.e. the transistor cells, are arranged parallel to each other. In other examples (not illustrated), the semiconductor device 1 may include one or more areas in which the stripes, i.e. the transistor cells, have a different orientation. For example, in at least one first area, the stripes, i.e. the transistor cells, have a first orientation. In at least one second area, the stripes, i.e. the transistor cells, have a second orientation which is rotated by an angle relative to the first orientation. E.g. the stripes in the first area are rotated by 90 degrees relative to the stripes in the second area.

FIG. 3 schematically and exemplarily illustrates a section of a horizontal projection of a power semiconductor device 1, in one example illustrating a section of a power-cell of the semiconductor device 1 as described with regard to FIG. 2. The power semiconductor device 1 comprises a plurality of trenches 14. The extension of the trenches 14 along the first lateral direction x defines the trench length l_{trench} (illustrated in FIG. 2). The spacing of the trenches 14 is determined by the pitch d_{pitch}, defined as the center-to-center distance between two adjacent trenches 14 along the second lateral direction y. Each trench 14 extends from the semiconductor substrate surface 111 into the semiconductor substrate 11 along the vertical direction z. Each trench 14 comprises a trench electrode 141 (also referred to as a gate electrode or as a source/emitter electrode) which is isolated from the semiconductor substrate 11 by a trench insulator 142. The trench electrode 141 may be at a gate potential, e.g. at one of a plurality of independent gate potentials, or at a source/emitter potential. Two adjacent trenches 14 laterally confine a mesa 15 of the semiconductor substrate 11. The semiconductor device 1 comprises a semiconductor body region 12 in the mesa 15. The body region 12 is of a second conductivity type. In each transistor cell, one or more source regions 13 may be provided. In the depicted section of the transistor cell, two source regions 13 of the first conductivity type are exemplarily illustrated. Each source region 13 has a length extension l_{source} along the first lateral direction x, and a width extension w_{source} along the second lateral direction y. In the present example, the source region 13 has an essentially rectangular shape, but other shapes are also possible, e.g. a rounded rectangular shape, an elliptical shape or any other shape. Irrespective of the shape, the length extension l_{source} is defined as the maximal extension of the source region along the first lateral direction x, and the width extension w_{source} is defined the maximal extension along the second lateral direction y. The length extension l_{source} and the width extension w_{source} are chosen such that source region 13 covers only part of the body region 12 in the mesa 15 along the first lateral direction x and at least part of the body region 12 in the mesa 15 along the second lateral direction y. For example, the length extension l_{source} is smaller than the trench length l_{trench}. Multiple source regions 13 may be arranged in a transistor cell and may be separated by a distance d_{source-source}. In the present example, the source-region length l_{source} is between 200-1300 nm, in one example between 500-1000 nm and the source-source separation along the first lateral direction x, d_{source-source}, is at least 200 nm, in one example larger than 400 nm. The source region 13 may be a source island 13a, i.e. a discrete region with a width extension w_{source} smaller or equal to the sum of the pitch d_{pitch} and the trench width w_{trench}. E.g. the source island 13a extends from middle trench to middle trench. In the present example, the source region 13, or source island 13a, has a width extension w_{source} that is larger than half a pitch, d_{pitch}/2, and smaller than a pitch d_{pitch}. The source island 13a at least partially covers a trench 14 and the body region 12 in the mesa 15 at least up to half a mesa width along the second lateral direction y, wₘₑₛₐ/2, wherein the mesa width wₘₑₛₐ, is the extension of the mesa 15 along the second lateral dimension y at the semiconductor substrate surface 111. In the present example, the source region 13 of the first conductivity type may be of n-type, or of n+−-type, or of n++-type. The body region 12 of the second conductivity type may be of p-type, or p+-type, or p++-type. In some alternative embodiments, the first conductivity type may be n-type and the second conductivity type may be p-type, or p++-type. An insulation layer 18 (not shown; cf. e.g. FIG. 3A) is arranged above and/or on the source region 13. In the present FIG. 3, the insulation layer 18 is not depicted in order not to obscure the relative arrangement of source region 13 and body region 12 in the mesa 15. The power semiconductor device 1 further comprises a recess 16 formed in the mesa 15. The recess 16 extends from an upper surface of the insulation layer 18 (not shown) along the vertical direction z through the source region 13, e.g. the source island 13a, into the body region 12. The recess 16 provides a groove for contacting the source region 13, e.g. the source island 13a, and body region 12. In one example, a contact plug (not depicted) extends into the recess 16 to contact both the source region 13, e.g. the source island 13a, and the body region 12, wherein the source region 13, e.g. the source island 13a, is contacted by the contact plug at least at one sidewall portion 162a, 162b. Hence, the recess 16 is also referred to as contact groove 16. The recess 16 extends along the first lateral direction x. The recess 16 has a length extension, l_{recess}, along the first lateral direction x, and a width extension, w_{recess}, along the second lateral direction y. In the present example, the recess 16 has an essentially rectangular shape, i.e. the horizontal cross-section of the recess 16 in the semiconductor substrate surface 111 has the shape of a rectangle, wherein the length extension, l_{recess}, exceeds its width extension, w_{recess}. Other shapes, such as a rounded rectangular shape, are also possible. The recess 16 extends parallel to the trenches 14 along the first lateral direction x. In the present example, the recess 16 is provided at the center of the mesa 15, i.e. in the middle between two adjacent trenches 14 or at half-pitch d_{pitch}/2 distance from the center of one of the adjacent trenches 14. The recess 16 is spaced apart along the second lateral direction y from each of the two adjacent trenches 14. The extension of the recess 16 along the second lateral direction y is referred to as recess width or contact-groove width, w_{recess}. In one example, the recess 16 and the source island 13a are arranged relative to each other along the second lateral direction y such that the recess 16 and the source island 13a overlap at least partially in the second lateral direction y. In the present example, the source island 13a and the recess 16 overlap over the entire recess width w_{recess}. However, any overlap between the entire recess width w_{recess} and half the recess width, w_{recess}/2, is possible. The recess 16 comprises an interruption 161 across at least part of the source region 13, e.g. source island 13a. Thus, the recess 16 comprises a segmentation in two parts at each source region 13, e.g. at each source island 13a. The length extension of the interruption 161, lᵢₙₜₑᵣᵣᵤₚₜᵢₒₙ, is smaller than the length extension of the source region 13, l_{source}. For example, the length extension of the interruption 161, lᵢₙₜₑᵣᵣᵤₚₜᵢₒₙ, is chosen such that the recess 16 overlaps with the source region 13, e.g. the source island 13a. The difference between the length extension of the source region 13, l_{source}, and the length extension of the interruption 161, lᵢₙₜₑᵣᵣᵤₚₜᵢₒₙ, determines the length of a contact overlap, l_{contact}, for contacting the source region 13 through a contact plug positioned in the recess 16. For example, the interruption 161 is located relative to the source region 13, e.g. the source island 13a, along the first lateral direction x such that the source region 13, e.g. the source island 13a, can be contacted through the recess 16 along the first lateral direction x on both sides of the interruption 161. That means, the interruption 161 is formed such that the recess 16 extends into or intersects with the source region 13 on a first side of the interruption 161 and on a second side of the interruption 161 along the first lateral direction x.

FIG. 3A schematically and exemplarily illustrates a vertical cross-section along line A-A′ as indicated in FIG. 3 in accordance with one embodiment of a power semiconductor device 1. The recess 16 comprises two sidewall portions 162a, 162b and a bottom portion 163. The recess 16 has a rectangular cross-section or a rounded rectangular cross-section. Other cross-sections such as a U-shaped cross-section or a semi-elliptical cross-section are also possible. In FIG. 3A, the insulation layer 18, not shown in FIG. 3, is depicted. As described with regard to FIG. 3, the source region 13 covers the body region 12 in the mesa 15 along the second lateral direction y across only part of the mesa width, wₘₑₛₐ. The source region 13 and the recess 16 are located relative to each other in the mesa 15 such that only one of the sidewall portions 162a exposes the source region 13. The other sidewall portion 162b does not expose the source region 13. Therefore, the present example may be referred to as a power semiconductor device 1 with a contact groove, or recess 16, with a one-sided source, i.e. one-sided source region 13. The recess 16 extends vertically into the source region 13 and into the body region 12 such that the bottom portion 163 of the recess 16 exposes the body region 12. An implant 17 of the second conductivity type, e.g. a p+-type or p++-type implant, is formed at the bottom portion 163 of the recess 16.

FIG. 3B schematically and exemplarily illustrates a vertical cross-section along line A-A′ as indicated in FIG. 3 in accordance with one embodiment of a power semiconductor device 1. In the following, only the differences to the embodiment described with regard to FIG. 3A are described. The embodiment depicted in FIG. 3B differs from the embodiment depicted in and described with regard to FIG. 3A in that a width of the recess 16 in the insulation layer 18, w_{recess,1}, is larger than the width of the recess 16 in the body region 12, w_{recess,2}. Hence, the recess 16 has a rectangular cross-section with a stepped profile. Other cross-sections are, however, also possible, e.g. a rectangular cross-section, a rounded rectangular cross-section, a U-shaped cross-section or a semi-elliptical cross-section, each with the stepped profile that arises from a larger recess width in the insulation layer 18, w_{recess,1}, as compared to the recess width in body region 12, w_{recess,2}. While in the examples of FIGS. 3A, 3B, the implant 17 does not extend over the entire bottom portion 163 of the recess 16, in other examples (not illustrated), the implant 17 does extend over the entire bottom portion 163 of the recess 16.

FIG. 3C schematically and exemplarily illustrates a vertical cross-section along line B-B′ as indicated in FIG. 3 in accordance with either the embodiment depicted in FIG. 3A or the embodiment depicted in FIG. 3B. For several reasons, it is desirable to choose the mesa width, wₘₑₛₐ, as small as possible. An interruption 161 of the recess 16 is provided across the source region 13, e.g. the source island 13a, along the first lateral direction x to reduce the diffusion of implant ions into the source region 13, e.g. the source island 13a, and a resulting change of the gate threshold voltage of the device 1. Hence, the contact overlap between the recess 16, i.e. the contact groove, and the source region 13, e.g. the source island 13a, is reduced. The interruption 161 may provide a shielding of the implant 17 of the second conductivity type, e.g. a p-type or p++-type implant, from the channel region by separation of the channel region from the recess 16, i.e. the contact groove.

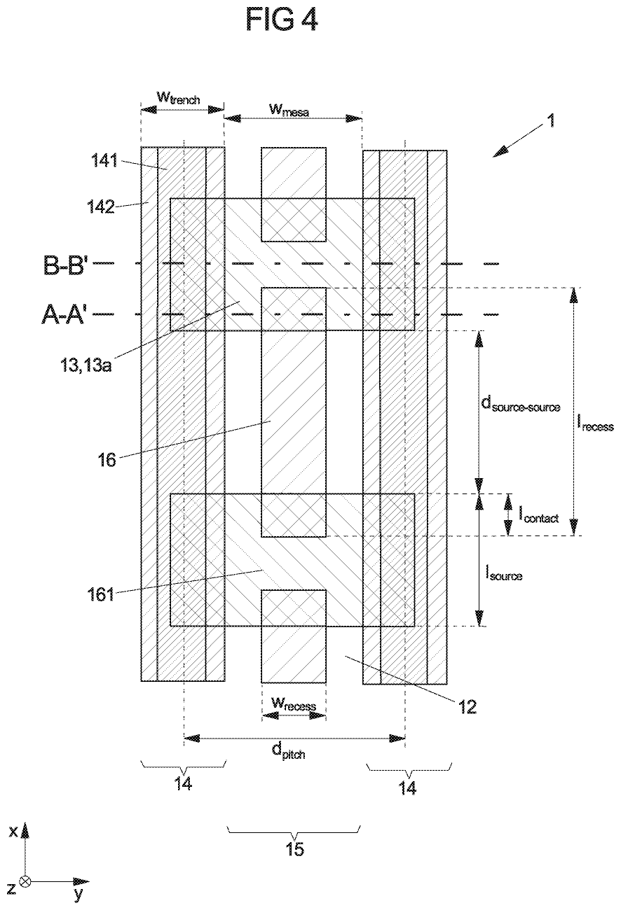

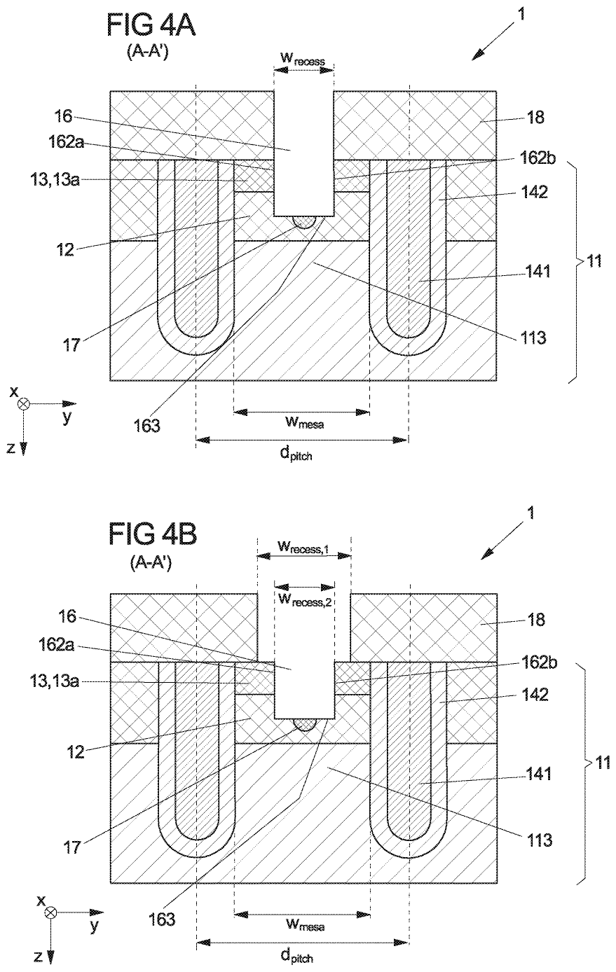

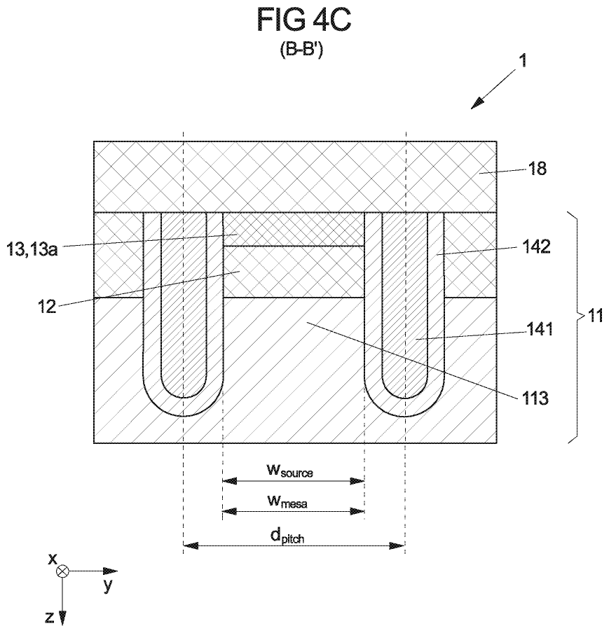

FIG. 4 schematically and exemplarily illustrates a section of a horizontal projection of a power semiconductor device 1, in one example a section of a power-cell of the semiconductor device 1 according to an alternative embodiment is described. The embodiment of FIG. 4 differs from the embodiment depicted in and described with regard to FIG. 3 in the arrangement and dimensions of the source region 13, e.g. the source island 13a. In the following, only the differences to the embodiment described in FIG. 3 are described. All other features described with regard to the embodiment of FIG. 3 apply to this embodiment as well. The source region 13 is a source island 13a. However, in the present embodiment, the source region 13 covers the body region 12 in the mesa 15 along the second lateral dimension y across the entire width of the mesa 15, wₘₑₛₐ. In one example, the width of the source region 13, w_{source}, is equal or larger than one pitch, d_{pitch}, but smaller than the sum of the pitch, d_{pitch}, and the trench width, w_{trench}, or no larger than twice the pitch, 2·d_{pitch}.

FIG. 4A schematically and exemplarily illustrates a vertical cross-section along line A-A′ as indicated in FIG. 4 in accordance with one embodiment of a power semiconductor device 1. The recess 16 comprises two sidewall portions 162a, 162b and a bottom portion 163. The recess 16 has a rectangular cross-section or a rounded rectangular cross-section. Other cross-sections such as a U-shaped cross-section or a semi-elliptical cross-section are also possible. In FIG. 4A, the insulation layer 18, not shown in FIG. 4, is depicted. As described with regard to FIG. 4, the source island 13a covers the body region 12 in the mesa 15 along the second lateral direction y across the entire mesa width, wₘₑₛₐ. Therefore, both sidewall portions 162a, 162b expose the source island 13a. Thus, the present example may be referred to as a power semiconductor device 1 with a contact groove, or recess 16, with a two-sided source, or source region 13. The recess 16 extends vertically into the source region 13, e.g. the source island 13b, and into the body region 12 such that the bottom portion 163 of the recess 16 exposes the body region 12. An implant 17 of the second conductivity type, e.g. an p-type or p++-type implant, is formed at the bottom portion 163 of the recess 16. While in the examples of FIGS. 4A, 4B, the implant 17 does not extend over the entire bottom portion 163 of the recess 16, in other examples (not illustrated), the implant 17 does extend over the entire bottom portion 163 of the recess 16.

FIG. 4B schematically and exemplarily illustrates a vertical cross-section along line A-A′ as indicated in FIG. 4 in accordance with an alternative embodiment of a power semiconductor device 1. In the following, only the differences to the embodiment described with regard to FIG. 4A are described. The embodiment depicted in FIG. 4B differs from the embodiment of FIG. 4A in that a width of the recess 16 in the insulation layer 18, w_{recess,1}, is larger than the width of the recess 16 in the body region 12, w_{recess,2}. Hence, the recess 16 has a rectangular cross-section with a stepped profile. Other cross-sections are, however, also possible, e.g. a rectangular cross-section, a rounded rectangular cross-section, a U-shaped cross-section or a semi-elliptical cross-section, each with the stepped profile that arises from a larger recess width in the insulation layer 18, w_{recess,1}, as compared to the recess width in body region 12, w_{recess,2}.

FIG. 4C schematically and exemplarily illustrates a vertical cross-section along line B-B′ as indicated in FIG. 4 in accordance with either the embodiment depicted in FIG. 4A or the embodiment depicted in FIG. 4B. For several reasons, it is desirable to choose the mesa width, wₘₑₛₐ, as small as possible. An interruption 161 of the recess 16 is provided across the source region 13, e.g. the source island 13a, along the first lateral direction x. Hence, the contact overlap, i.e. the overlap between the recess 16, i.e. the contact groove, and the source region 13 is reduced. The interruption 161 provides a shielding of the implant 17 of the second conductivity type, e.g. a p-type or a p++-type implant, from the channel region by separation of the channel region from the recess 16, i.e. the contact groove.

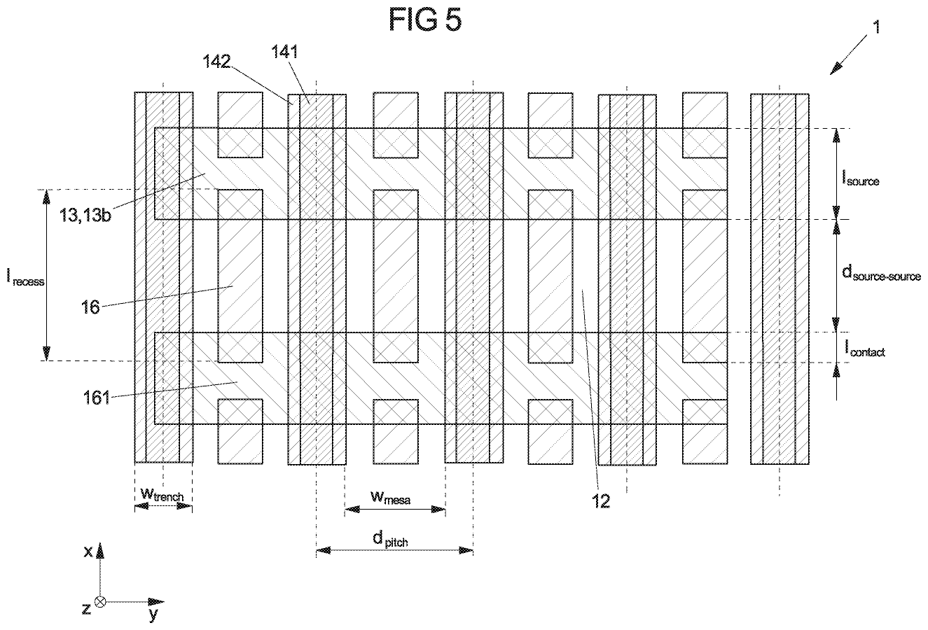

FIG. 5 schematically and exemplarily illustrates a section of a horizontal projection of a power semiconductor device 1, for example a section comprising a plurality of transistor cells of the semiconductor device 1 according to an alternative embodiment is described. The described embodiment differs from the previously described embodiments of FIG. 3, in the arrangement and extension of the source region 13. The source region 13 in the present embodiment is a source stripe 13b. That means, the source region 13 extends across multiple periods of the stripe-cell configuration, e.g. across multiple pitches, i.e. two pitches or more. Each of the transistor cells may exhibit a structure as described with regard to FIGS. 4, 4A-4C, i.e. a two-sided source, or source region 13. The first and the last transistor cells comprising the source stripe 13b may each exhibit a structure as described with regard to FIGS. 3, 3A-3C or a structure as described with regard to FIGS. 4, 4A-4C. I.e. the first transistor cell and the last transistor cell may each comprise a one-sided source 13 or may each comprise a two sided-source 13, or one of them (e.g. the first transistor cell) may comprise a one-sided source 13 and the other one (e.g. the second transistor cell) may comprise a two-sided source 13. In the present example, the first transistor cell comprises a two-sided source 13, and the last transistor cell comprises a one-sided source 13. In each transistor cell, the source region 13, 13b can be contacted via the recess 16 on a first side of the interruption 161 and on a second side of the interruption 161 along the first lateral direction x. In all other aspects, the features described with regard to FIG. 3, 3A-3C and FIG. 4, 4A-4C may apply accordingly. Again, an insulation layer 18 is not shown in order not to obscure the relative arrangement of source stripe 13b, body region 12 and the trenches 14.

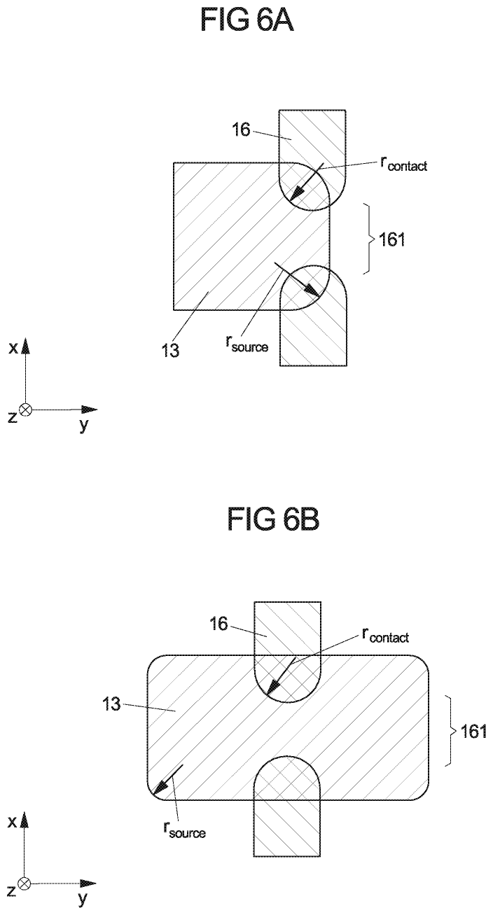

FIG. 6A schematically and exemplarily illustrates a section of a horizontal projection of a power semiconductor device 1 in accordance with one or more embodiments. In one example, FIG. 6A illustrates the details of the contact overlap, i.e. the overlap between the recess 16 and the source region 13, for example in case of a one-sided source as depicted e.g. in FIGS. 3, 3A-3C for a source island 13a, as well as e.g. in FIG. 5 for a source stripe 13b in the last transistor cell′. Due to manufacturing constraints, the source region 13 as well as the recess 16 may have rounded corners in a horizontal plane spanned by the first and the second lateral directions x and y, e.g. in the semiconductor substrate surface 111. The corner radius, r_{source}, of the corners of the source region 13 as measured in a plane spanned by the first and the second lateral dimension, e.g. in the semiconductor substrate surface 111, is larger than zero. For example, the corner radius, r_{source}, of the source region 13 is larger than 5 nm, in one example larger than 10 nm and smaller than half the length extension, l_{source}, of the source region 13 in the first lateral direction x. A horizontal cross-section of the recess 16 in the semiconductor substrate surface 111 has a U-shape, i.e. the rectangular cross-section of the recess 16 transitions into curved, semicircular terminations on both sides of the interruption 161 along the first lateral direction x. The radius of the semicircular terminations, r_{contact}, is e.g. larger than 5 nm, in one example larger than 10 nm and smaller than half the width of the recess 16, w_{recess}, in the semiconductor substrate surface 111 in a straight segment 164 of the recess 16.

FIG. 6B schematically and exemplarily illustrates a section of a horizontal projection of a power semiconductor device 1 in accordance with one or more embodiments. FIG. 6B illustrates the overlap between the recess 16 and the source region 13 in case of a two-sided source as depicted e.g. in FIGS. 4, 4A-4C for a source island 13b, or in FIG. 5 for a source stripe 13b. As described with regard to FIG. 6A, a horizontal section of the source region 13, e.g. in the semiconductor substrate surface 111, has rounded corners, where the corner radius, r_{source}, as measured in a plane spanned by the first and the second lateral directions (x-y plane) is between 5 nm, in one example 10 nm, and half the length extension, l_{source}, of the source region 13 in the first lateral direction x. The straight segments 164 of the recess 16 transition into curved, semicircular terminations on both sides of the interruption 161 along the first lateral direction x in the semiconductor substrate surface 111. The radius of these semicircular terminations, r_{contact}, as measured in a horizontal plane spanned by the first and second lateral directions (x-y-plane), e.g. in the semiconductor substrate surface 111, is e.g. between 5 nm, in one example 10 nm, and half the recess width, w_{recess}/2.

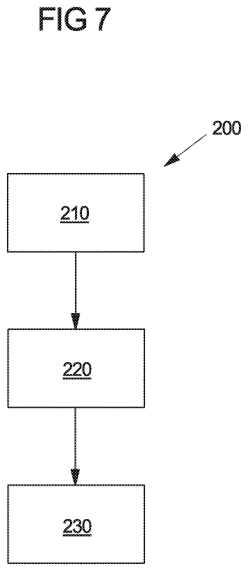

FIG. 7 schematically and exemplarily illustrates a method 200 of producing a power semiconductor device 1 in accordance with one or more embodiments. The power semiconductor device 1 comprises a semiconductor substrate 11 with a drift region 113 of the first conductivity type, e.g. an n-type. The power semiconductor device 1 further comprises a plurality of trenches 14 in the semiconductor substrate 11, wherein two adjacent trenches 14 laterally confine a mesa 15 of the semiconductor substrate 11. Each trench 14 extends from a semiconductor substrate surface 111 into the semiconductor substrate 11 along a vertical direction z. Each trench 14 comprises a trench electrode 141 (or gate electrode or source/emitter electrode). The trench electrode 141 may be at a gate potential, e.g. at one of a plurality of independent gate potentials, or at a source/emitter potential. The trench electrode 141 is isolated from the semiconductor substrate 11 by a trench insulator 142. The power semiconductor device 1 comprises a body region 12 of a second conductivity type, e.g. p-type, in the mesa 15. The method 200 comprises the step of forming 210 a semiconductor source region, or source region 13 of the first conductivity type, e.g. an n-type. The source region 13 has a length extension, l_{source}, along a first lateral direction x parallel to a length extension, l_{trench}, of the plurality of trenches 14 and a width extension, w_{source}, along a second lateral direction y perpendicular to the length extension, l_{trench}, of the plurality of trenches 14. The source region 13 covers only part of the body region 12 in the mesa 15 along the first lateral direction x. The source region 13 covers at least part of the body region 12 in the mesa 15 along the second lateral direction y. The source region 13 is formed, e.g. as a source island 13a. Alternatively, the source region 13 is a source stripe 13b. Wherein a source island 13a has e.g. a width extension, w_{source}, larger than half pitch, d_{pitch}/2, and smaller than twice the pitch, 2·d_{pitch}, a source stripe 13b extends across or at least partly across a plurality of mesas 15. E.g. the width extension, w_{source}, of a source stripe 13b is larger than one and a half pitch, 1.5·d_{pitch}. The method further comprises the step of forming 220 an insulation layer 18 above and/or on the source region 13. The insulation layer 18 may be directly deposited on the source region 13. Alternatively, an intermediate layer may be arranged between the insulation layer 18 and the source region 13. The insulation layer 18 may cover the source region 13 and the body region 12 in the mesa 15, as well as the trenches 14. A recess 16 is formed 230 in the mesa 15. The recess 16 extends from an upper surface of the insulation layer 18 along the vertical direction z through the source region 13 into the body region 12. The recess 16 extends along the first lateral direction x and comprises an interruption 161 across at least part of the source region 13. The recess 16 is, e.g. formed with a cross-section of a rounded rectangular shape in a vertical plane spanned by the vertical direction z and the second lateral direction y. Other cross-sections such as a U-shaped or an elliptical cross-section may also be possible. The recess 16 may be formed with a width extension of the recess 16 along the second lateral direction y, w_{recess}, in the insulation layer 18, and in the source region 13 and body region 12. Alternatively, the recess 16 may be formed with a first width extension, w_{recess,1}, in the layers below the insulation layer 18, i.e. in the source region 13 and in the body region 12, and a second width extension, w_{recess,2}, in the insulation layer 18. Hence, the recess 16 has a rounded rectangular cross-section in a vertical plane spanned by the vertical direction z and the second lateral direction y with a stepped profile. Also, other cross-sections such as a U-shaped or an elliptical cross-section can be combined with the stepped profile. The recess 16 is formed with a length extension, l_{recess}, along the first lateral direction x. For example, the length extension, l_{recess}, is given by the trench length, l_{trench}. The recess 16 forms a contact groove in the mesa 15. The source region 13 may be contacted by a contact-plug structure provided in the recess 16. The recess 16 has e.g. two sidewall portions 162a, 162b and a bottom portion 163. Depending on the relative arrangement of source region 13 and recess 16, the source region 13 may be contacted by a contact-plug structure provided in the recess 16 at one sidewall portion 162a or 162b or at both sidewall portions 162a, 162b. This is referred to as one-sided source or two-sided source, respectively. At the bottom portion 163, an implant 17 of the second conductivity type, e.g. a p-type or p++-type implant may be provided. The interruption 161 provided in the recess 16 across the source region 13, leads to a reduced contact overlap, i.e. a reduced overlap between the recess 16 and the source region 13. This may reduce implant diffusion into the channel, compromising device 1 performance. For example, the interruption 161 is provided in the recess 16 such that an overlap between the source region 13 and the recess 16 exists on both sides of the interruption 161 along the first vertical direction x. Thus, the source region 13 can be contacted by a contact-plug structure arranged in the recess 16 on both sides of the interruption 161 along the first lateral direction x. This may reduce the risk of a latch-up.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. The features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

Examples of the present invention are summarized here. Other examples can also be understood from the entirety of the specification and the claims filed herein.
Example 1: A power semiconductor device, comprising: a semiconductor substrate with a drift region of a first conductivity type; a plurality of trenches, wherein two adjacent trenches laterally confine a mesa of the semiconductor substrate, wherein each trench extends from a semiconductor substrate surface into the semiconductor substrate along a vertical direction and comprises a trench electrode isolated from the semiconductor substrate by a trench insulator; a semiconductor body region of a second conductivity type in the mesa; a semiconductor source region of the first conductivity type, wherein the source region has a length extension, l_{source}, along a first lateral direction parallel to a length extension, l_{trench}, of the plurality of trenches and a width extension, w_{source}, along a second lateral direction perpendicular to the length extension, l_{trench}, of the plurality of trenches, wherein the source region covers only part of the semiconductor body region in the mesa along the first lateral direction and covers at least part of the semiconductor body region in the mesa along the second lateral direction; an insulation layer above and/or on the source region; and a recess in the mesa extending from an upper surface of the insulation layer along the vertical direction through the source region into the semiconductor body region, wherein the recess extends along the first lateral direction and comprises an interruption across at least part of the source region.
Example 2: The power semiconductor device according to example 1, wherein the recess comprises two sidewall portions and a bottom portion; and wherein the recess comprises a rectangular cross-section, or a rounded rectangular cross-section, or a U-shaped cross-section, or a semi-elliptical cross-section in a plane spanned by the second lateral direction and the vertical direction.
Example 3: The power semiconductor device according to one of the examples 1 or 2, wherein the source region covers the semiconductor body region in the mesa along the second lateral dimension across a mesa width, wₘₑₛₐ, wherein the mesa width, wₘₑₛₐ, is the extension of the mesa along the second lateral dimension at the semiconductor substrate surface.
Example 4: The power semiconductor device according to one of the examples 1 to 2, wherein the source region covers the semiconductor body region in the mesa along the second lateral dimension across only part of a mesa width, wₘₑₛₐ, wherein the mesa width, wₘₑₛₐ, is the extension of the mesa along the second lateral dimension at the semiconductor substrate surface.
Example 5: The power semiconductor device according to one of the examples 2 to 4, wherein the source region and the recess are located relative to each other in the mesa such that both sidewall portions of the recess expose the source region.
Example 6: The power semiconductor device according to one of the examples 2 to 4, wherein the source region and the recess are located relative to each other in the mesa such that only one of the sidewall portions of the recess exposes the source region and the other sidewall portion of the recess does not expose the source region.
Example 7: The power semiconductor device according to one of the examples 1 to 6, wherein the recess extends vertically into the source region and into the semiconductor body region such that the bottom portion of the recess exposes the semiconductor body region.
Example 8: The power semiconductor device according to one of the examples 1 to 7, wherein an implant of the second conductivity type is formed at the bottom portion of the recess.
Example 9: The power semiconductor device according to one of the examples 1 to 8, wherein a width, w_{recess,1}, of the recess along the second lateral dimension in the insulation layer is larger than a width, w_{recess,2}, of the recess along the second lateral dimension in the source region and a width, w_{recess,2}, of the recess along the second lateral dimension in the semiconductor body region, such that the cross-section of the recess in a plane spanned by the vertical direction and the second lateral direction comprises a stepped profile.
Example 10: The power semiconductor device according to one of the examples 2 to 9, wherein a contact plug extends into the recess to contact both the source region and the semiconductor body region, wherein the source region is contacted by the contact plug at least at one sidewall portion.
Example 11: The power semiconductor device according to one of the examples 2 to 10, wherein the source region has a rounded rectangular shape, wherein the length extension, l_{source}, is determined by a length along the first lateral direction and wherein the width extension, w_{source}, is determined by a width along the second lateral dimension and wherein a length extension, lᵢₙₜₑᵣᵣᵤₚₜᵢₒₙ, of the interruption of the recess s smaller than the length extension, l_{source}, of the source region.
Example 12: The power semiconductor device according to one of the examples 2 to 11, wherein the source region is a source island, wherein the width, w_{source}, of the source island corresponds to a center-to-center distance between adjacent trenches of the plurality of trenches or wherein the width of the source island, w_{source}, corresponds to half of the center-to-center distance between adjacent trenches.
Example 13: The power semiconductor device according to one of the examples 1 to 12, wherein the source region is a source stripe extending across a plurality of adjacent mesas.
Example 14: The power semiconductor device according to one of the examples 1 to 13, wherein the power semiconductor device comprises a plurality of source regions spaced apart from each other along the first lateral direction.
Example 15: A method of producing a power semiconductor device that includes, in a semiconductor substrate, a drift region of a first conductivity type, a plurality of trenches, wherein two adjacent trenches laterally confine a mesa of the semiconductor substrate, wherein each trench extends from a semiconductor substrate surface into the semiconductor substrate along a vertical direction and comprises a trench electrode isolated from the semiconductor substrate by a trench insulator, and a semiconductor body region of a second conductivity type in the mesa, the method comprising: forming a semiconductor source region of the first conductivity type, wherein the source region has a length extension along a first lateral direction parallel to a length extension of the plurality of trenches and a width extension along a second lateral direction perpendicular to the length extension of the plurality of trenches, wherein the source region covers only part of the semiconductor body region in the mesa along the first lateral direction and covers at least part of the semiconductor body region in the mesa along the second lateral direction; forming an insulation layer above and/or one the source region; forming a recess in the mesa extending from an upper surface of the insulation layer along the vertical direction through the source region into the semiconductor body region, wherein the recess extends along the first lateral direction and comprises an interruption across at least part of the source region.

What is claimed is:

1. A power semiconductor device, comprising:
a semiconductor substrate with a drift region of a first conductivity type;
a plurality of trenches, wherein two adjacent trenches laterally confine a mesa of the semiconductor substrate, wherein each trench extends from a semiconductor substrate surface into the semiconductor substrate along a vertical direction and comprises a trench electrode isolated from the semiconductor substrate by a trench insulator;
a semiconductor body region of a second conductivity type in the mesa;
a semiconductor source region of the first conductivity type, wherein the source region has a length extension along a first lateral direction parallel to a length extension of the plurality of trenches and a width extension along a second lateral direction perpendicular to the length extension of the plurality of trenches, wherein the source region covers only part of the semiconductor body region in the mesa along the first lateral direction and covers at least part of the semiconductor body region in the mesa along the second lateral direction;
an insulation layer above and/or on the source region; and
a recess in the mesa extending from an upper surface of the insulation layer along the vertical direction through the source region into the semiconductor body region,
wherein the recess extends along the first lateral direction and comprises an interruption across at least part of the source region.

2. The power semiconductor device of claim 1, wherein the recess comprises two sidewall portions and a bottom portion, and wherein the recess has a rectangular cross-section, a rounded rectangular cross-section, a U-shaped cross-section, or a semi-elliptical cross-section in a plane spanned by the second lateral direction and the vertical direction.

3. The power semiconductor device of claim 2, wherein the source region and the recess are located relative to each other in the mesa such that only one of the sidewall portions of the recess exposes the source region and the other sidewall portion of the recess does not expose the source region.

4. The power semiconductor device of claim 2, wherein the source region and the recess are located relative to each other in the mesa such that both sidewall portions of the recess expose the source region.

5. The power semiconductor device of claim 2, wherein a contact plug extends into the recess to contact both the source region and the semiconductor body region, and wherein the source region is contacted by the contact plug at least at one of the two sidewall portions.

6. The power semiconductor device of claim 1, wherein the source region covers the semiconductor body region in the mesa along the second lateral dimension across a mesa width, and wherein the mesa width is an extension of the mesa along the second lateral dimension at the semiconductor substrate surface.

7. The power semiconductor device of claim 1, wherein the source region covers the semiconductor body region in the mesa along the second lateral dimension across only part of a mesa width, and wherein the mesa width is an extension of the mesa along the second lateral dimension at the semiconductor substrate surface.

8. The power semiconductor device of claim 1, wherein the recess extends vertically into the source region and into the semiconductor body region, such that the bottom portion of the recess exposes the semiconductor body region.

9. The power semiconductor device of claim 1, wherein an implant of the second conductivity type is formed at the bottom portion of the recess.

10. The power semiconductor device of claim 1, wherein a width of the recess along the second lateral dimension in the insulation layer is larger than a width of the recess along the second lateral dimension in the source region and a width of the recess along the second lateral dimension in the semiconductor body region, such that a cross-section of the recess in a plane spanned by the vertical direction and the second lateral direction comprises a stepped profile.

11. The power semiconductor device of claim 1, wherein the source region has a rounded rectangular shape, wherein the length extension is determined by a length along the first lateral direction, wherein the width extension is determined by a width along the second lateral dimension, and wherein a length extension of the interruption of the recess is smaller than the length extension of the source region.

12. The power semiconductor device of claim 1, wherein the source region is a source island, wherein the width of the source island corresponds to a center-to-center distance between adjacent trenches of the plurality of trenches or the width of the source island corresponds to half of the center-to-center distance between adjacent trenches.

13. The power semiconductor device of claim 1, wherein the source region is a source stripe extending across a plurality of adjacent mesas.

14. The power semiconductor device of claim 1, wherein the power semiconductor device comprises a plurality of source regions spaced apart from each other along the first lateral direction.

15. A method of producing a power semiconductor device that includes, in a semiconductor substrate, a drift region of a first conductivity type, a plurality of trenches, wherein two adjacent trenches laterally confine a mesa of the semiconductor substrate, wherein each trench extends from a semiconductor substrate surface into the semiconductor substrate along a vertical direction and comprises a trench electrode isolated from the semiconductor substrate by a trench insulator, and a semiconductor body region of a second conductivity type in the mesa, the method comprising:
forming a semiconductor source region of the first conductivity type, wherein the source region has a length extension along a first lateral direction parallel to a length extension of the plurality of trenches and a width extension along a second lateral direction perpendicular to the length extension of the plurality of trenches, wherein the source region covers only part of the semiconductor body region in the mesa along the first lateral direction and covers at least part of the semiconductor body region in the mesa along the second lateral direction;
forming an insulation layer above and/or one the source region; and
forming a recess in the mesa extending from an upper surface of the insulation layer along the vertical direction through the source region into the semiconductor body region, wherein the recess extends along the first lateral direction and comprises an interruption across at least part of the source region.
